(19) United States
(12) Patent Application Publication
(10) Pub. No.: US 2008/0157193 A1
(43) Pub. Date: Jul. 3, 2008

(54) Semiconductor device and method for fabricating the same

(75) Inventor: Sung Man Pang, Gwangmysong-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU HITEK CO., LTD.

(21) Appl. No.: 12/000,737

(22) Filed: Dec. 17, 2007

(30) Foreign Application Priority Data
Dec. 27, 2006 (KR) 10-2006-0134640

(51) Int. Cl. H01L 29/78; H01L 21/336

(52) U.S. Cl. 257/334; 257/330; 438/270; 257/E29.262; 257/E21.41

(57) ABSTRACT

A semiconductor device is provided. The semiconductor device includes a semiconductor substrate of a first conductivity type, an epitaxial layer of the first conductivity type on the semiconductor substrate, a base region of a second conductivity type on the epitaxial layer, the base region including subregions spaced apart from one another by a predetermined distance, a source region of the first conductivity type on the base region, a drain region of the first conductivity type between the subregions of the base region, a trench penetrating through the source region and the base region, a first gate conductive layer within the trench, and a second gate conductive layer on an exposed portion of the base region.

### RELATED APPLICATIONS

The present application claims the benefit of priority under 35 U.S.C. §119 to Korean Patent Application No. 10-2006-0134640, filed Dec. 27, 2006, the entire contents of which are incorporated herewith by reference.

### BACKGROUND

Embodiments consistent with the present invention relate to a semiconductor device and a method for fabricating the same. More particularly, embodiments consistent with the present invention relate to a power metal oxide semiconductor field effect transistor (power MOSFET), and a method for fabricating the same.

In general, a power MOSFET has an input impedance greater than that of a bipolar transistor. Thus, a gate driver circuit of the power MOSFET often comprises a simple structure. In addition, because the power MOSFET may be a unipolar device, no time delay is generated due to the accumulation or recombination of minority carriers while an electronic device is turned on/off.

Power MOSFETs may be used in, for example, a switching mode power supply, a lamp ballast, a motor driver circuit, etc. The power MOSFET device may include a drain-extended MOSFET structure using planar diffusion technology. On the other hand, studies have been conducted on a trench gate MOSFET structure, in which a trench may be formed by etching a semiconductor substrate and filled with a gate conductive layer. The trench gate MOSFET structure may include an increased cell density per unit area but may cause a junction field effect transistor (JFET) to have a reduced resistance between devices. Hence, the trench gate MOSFET structure may aid in the integration of semiconductor devices and may reduce source-drain on-resistance (Rds(on)) of the semiconductor devices.

Further, the trench gate MOSFET may be used as a single device, because a drain of the trench gate MOSFET is electrically connected to the bottom of a semiconductor substrate. Normally, it is difficult to integrate the trench gate MOSFET with a lateral-type device. Meanwhile, a channel of the drain extended MOSFET, which may be a high-power lateral-type device, is formed in a horizontal direction. Therefore, a large chip area is required for a power MOSFET to have a high voltage and high current capacity.

### SUMMARY

Embodiments consistent with the present invention provide a semiconductor device and a method for fabricating the same.

Embodiments consistent with the present invention provide a semiconductor device including a horizontal channel and a horizontal drain while maintaining a vertical channel structure, and a method for fabricating the same.

Embodiments consistent with the present invention provide a trench gate MOSFET, which can be implemented at a small area and can be integrated with other devices, and a method for fabricating the same.

In one embodiment, the semiconductor device includes a first gate region vertical to a substrate, a second gate region horizontal to the substrate, and a drain region connected to the substrate.

In one embodiment, the semiconductor device includes a semiconductor substrate of a first conductivity type, an epitaxial layer of the first conductivity type on the semiconductor substrate, a base region of a second conductivity type on the epitaxial layer, the base region including subregions spaced apart from one another by a predetermined distance, a source region of the first conductivity type on the base region, a drain region of the first conductivity type between the subregions of the base region, a trench penetrating through the source region and the base region, a first gate conductive layer within the trench, and a second gate conductive layer on an exposed portion of the base region.

In another embodiment, the method includes forming an epitaxial layer of a first conductivity type on a semiconductor substrate of the first conductivity type, forming a base region of a second conductivity type on the epitaxial layer, the base region including a plurality of subregions spaced apart from one another, forming a source region of the first conductivity type in the base region, and a heavily-doped region of the first conductivity type between the subregions of the base region, forming a trench passing through the source region and the base region, and forming a first gate conductive layer within the trench, and a second gate conductive layer on the base region.

The details of one or more embodiments are set forth in the accompanying drawings and the description below. Other features will be apparent from the description and the drawings, and from the claims.

### BRIEF DESCRIPTION OF THE DRAWINGS

FIG. 1 is a top view of a semiconductor device according to an embodiment consistent with the present invention.

FIG. 2 is a sectional view of a semiconductor device according to an embodiment consistent with the present invention.

FIG. 3 is a sectional view of a semiconductor device according to another embodiment consistent with the present invention.

FIG. 4 is a sectional view of a semiconductor device according to a further embodiment consistent with the present invention.

FIGS. 5 to 10 are sectional views illustrating a method for fabricating a semiconductor device according to an embodiment consistent with the present invention.

### DETAILED DESCRIPTION

Reference will now be made in detail to the embodiments consistent with the present disclosure, examples of which are illustrated in the accompanying drawings. In the drawings, like reference numerals are used to refer to like elements.

In the following description, it will be understood that when a layer (or film) is referred to as being on, above, or over another layer or substrate, it can be directly on, above, or over the another layer or substrate, or intervening layers may be present. Further, it will be understood that when a layer is referred to as being below, under, beneath, or lower than another layer, it can be directly below, under, beneath, or lower than the another layer, or one or more intervening layers may be present. In addition, it will also be understood that when a layer is referred to as being ‘between’ two layers, it can be the only layer between the two layers, or one or more intervening layers may be present between the two layers.

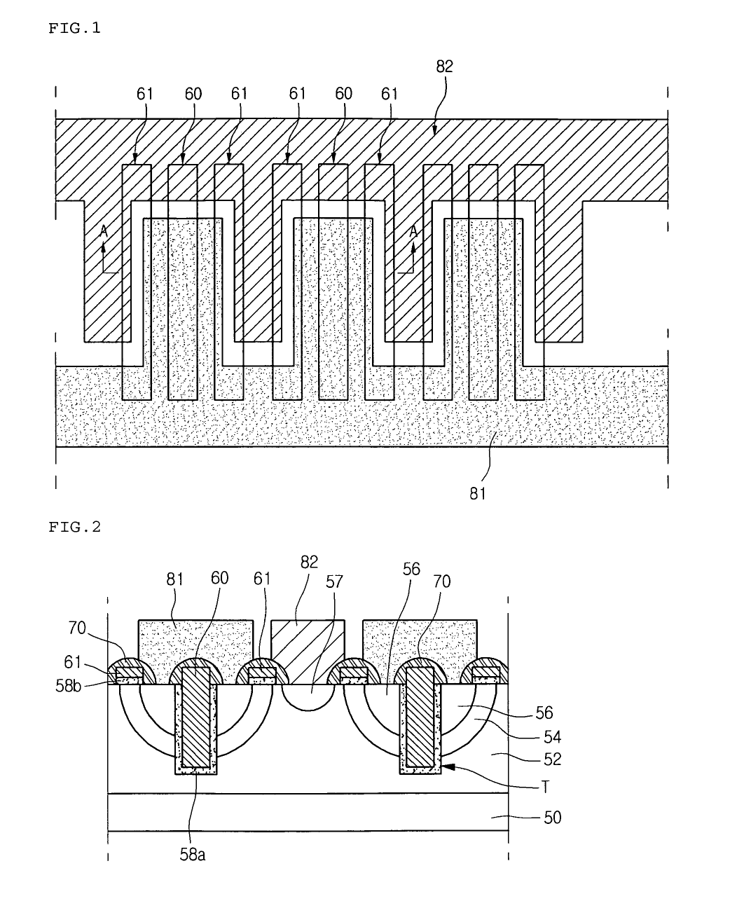

FIG. 1 is a plan view illustrating a trench gate MOSFET according to an embodiment consistent with the present invention. Referring to FIG. 1, the trench gate MOSFET includes a source line 81, a drain line 82, and gate conductive layers 60 and 61. Gate conductive layer 60 may fill in a trench (T), which will be described later, and gate conductive layer 61 may be formed on a base region. Gate conductive layers 60 and 61 may be connected with each other at end portions thereof. Hereinafter, the trench gate MOSFET will be described with reference to cross-sections taken along line A-A in FIG. 1.

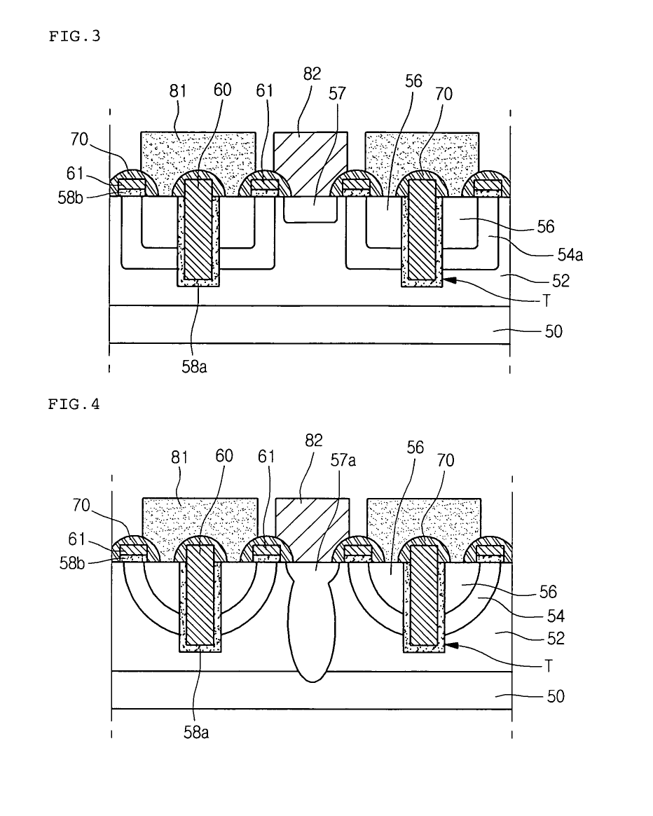

FIG. 2 is a sectional view illustrating a trench gate MOSFET according to an embodiment consistent with the present invention. Referring to FIG. 2, an epitaxial layer 52 is formed on a substrate 50. In one embodiment, substrate 50 may be a heavily-doped semiconductor substrate of a first conductivity type, e.g., an N-type substrate, and epitaxial layer 52 may be lightly-doped with N-type impurities. Further, a base region 54 may be formed within epitaxial layer 52. In one embodiment, base region 54 may be a lightly-doped base region of a second conductivity type, e.g., a P-type base region.

In epitaxial layer 52, a plurality of base regions 54 may be formed spaced apart from one another within a predetermined region. Base region 54 may be formed in various shapes. As shown in FIG. 2, base region 54 may have a semicircular cross-section and a semispherical or semicylindrical shape. As will be described later, base region 54 may also have a rectangular cross-section and a rectangular-pillar shape. The various shapes of base region 54 may be formed by appropriately controlling the doping concentration of base region 54. Of course, base region 54 is not limited to the above-mentioned shapes.

In general, a vertical channel and a horizontal channel may be simultaneously formed when the length of a base region under the horizontal gate is equal to the length of a side of the vertical gate, thereby allowing the semiconductor device to operate optimally. One way to optimally satisfy the above-described requirements is to form the base region in a semispherical or semicylindrical shape. The rectangular-pillar shaped base region may satisfy the above requirements. These shapes provide an appropriate adaptive characteristic according to manufacturing apparatuses and environments.

Referring again to FIG. 2, a source region 56 is formed within base region 54. In one embodiment, source region 56 may be heavily-doped with N-type impurities. A drain region 57 is formed between base regions 54. Consistent with the present invention, drain region 57 may be heavily doped with N-type ions. A trench T having a predetermined thickness is formed in epitaxial layer 52, penetrating through source region 56 and base region 54.

Gate insulating layers 58a and 58b, which may be, for example, formed of oxide, are formed on the surface of trench T and an exposed surface of base region 54 of the second conductivity type. A gate conductive layer 60 filling trench T is formed on gate insulating layer 58a, which is formed on the surface of trench T. A gate conductive layer 61 is formed on gate insulating layer 58b, which is formed on the exposed surface of base region 54.

An interlayer insulating layer 70 is formed on gate conductive layers 60 and 61. A source contact (not shown), a gate contact (not shown), and a drain contact (not shown) may be formed within interlayer insulating layer 70. A gate line layer (not shown), a source line layer 81, and a drain line layer 82 are formed on interlayer insulating layer 70. The gate line layer (not shown) may be electrically connected to gate conductive layers 60 and 61 through the gate contact (not shown). Source line layer 81 is electrically connected to source region 56 through the source contact (not shown). Drain line layer 82 is electrically connected to drain region 57 through the drain contact (not shown).

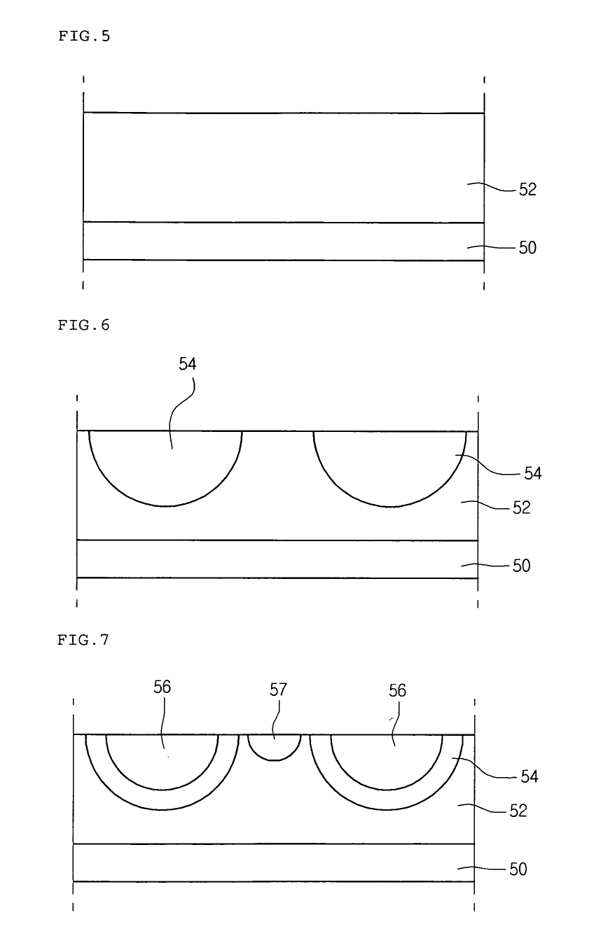

FIG. 3 is a sectional view illustrating a trench gate MOSFET according to another embodiment consistent with the present invention. Referring to FIG. 3, base region 54a has a rectangular cross-section and a rectangular-pillar shape. Drain region 57 is also formed in a rectangular-pillar shape. In FIGS. 2 and 3, like reference numerals are used to refer to like elements.

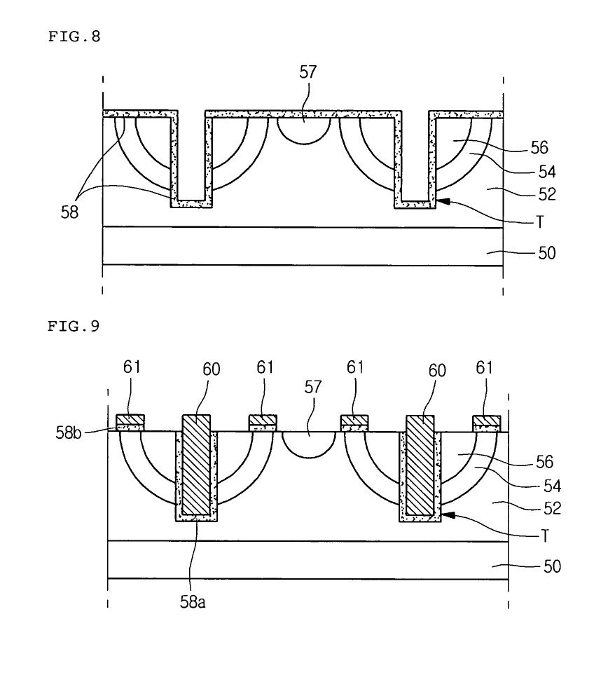

FIG. 4 is a sectional view illustrating a trench gate MOSFET according to a further embodiment consistent with the present invention. In FIGS. 3 and 4, like reference numerals are used to refer to like elements, except drain region 57. In this embodiment, a drain region 57a is connected to substrate 50, which may be a heavily-doped substrate of a first conductivity type, e.g., an N-type substrate. Base region 54 may be formed in a semispherical shape, a semicylindrical shape, or a rectangular-pillar shape.

Epitaxial layer 52 may have a doping concentration lower than that of substrate 50 or drain region 57a, thereby serving as a drain of the MOS device. This may increase a breakdown voltage of the MOS device, but may also increase the on resistance of the MOS device. As illustrated in FIG. 4, when drain region 57a extends into substrate 50, a current gathering at a relatively narrow region like drain region is dispersed to the extended drain region 57a. Further, this means that the on resistance component of drain line layer 82 may be reduced.

As discussed above, the shapes of base region 54 aim to provide appropriate adaptation according to the electrical/mechanical properties of the semiconductor device, and the manufacturing apparatuses and/or environments. The present invention is not limited to the specific shapes of base region 54 disclosed herein.

In the trench gate MOSFET according to the embodiments consistent with the present invention, the current has a component flowing through the channel formed by the horizontal gate conductive layer 61 and a component flowing through the channel formed by the vertical gate conductive layer 60.

A two-dimensional current flow, i.e., a vertical/horizontal current flow can be implemented by adjusting the sizes and the doping concentrations of source region 56 and base region 54. Source line layer 81 may form an ohmic contact by controlling an aspect ratio of source region 56 to base region 54, thereby providing a structure in which source region 56 and base region 54 are combined together.

A method for fabricating a trench gate MOSFET according to an embodiment consistent with the present invention will be described below.

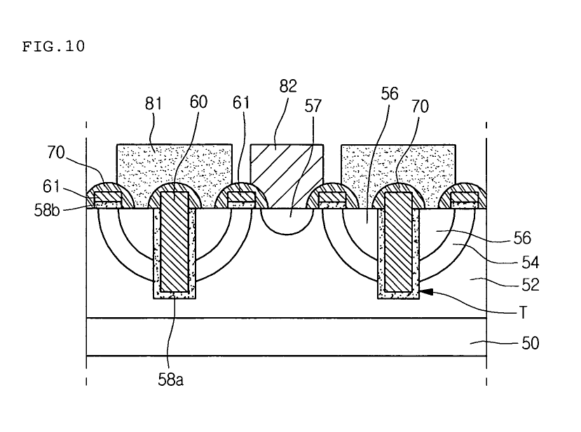

Referring to FIG. 5, an epitaxial layer 52 is formed on a substrate 50. In one embodiment, substrate 50 may be heavily doped to have a first conductivity type, e.g., an N-type, and epitaxial layer 52 may be lightly doped with N-type impurities.

Referring to FIG. 6, a base region 54 is formed in epitaxial layer 52. In one embodiment, base region 54 may be lightly doped to have a second conductivity type, e.g., a P-type base. Further, base region 54 may include a plurality of sub-regions formed in epitaxial region 52. The sub-regions are spaced apart from one another by a predetermined distance. Base region 54 may be formed in a semispherical shape, a semicylindrical shape, or a rectangular-pillar shape. However, base region 54 is not limited to these shapes.

Referring to FIG. 7, an N-type region 56 is formed by doping high-concentration ions of the first conductivity type, e.g., N-type ions, into base region 54. Further, a drain region 57 is formed by doping high-concentration ions of the first conductivity type, e.g., N-type ions, in epitaxial layer 52 between the sub-regions of base region 54.

Referring to FIG. 8, a trench T is formed to penetrate through source region 56 and base region 54, so as to expose substrate 50. An insulating layer 58 is then formed over substrate 50 and over the sidewalls and bottom of trench T.

Referring to FIG. 9, a conductive layer is formed over the resulting structure where insulating layer 58 is formed. In one embodiment, the conductive layer may be an impurity-doped polysilicon layer. The conductive layer and insulating layer 58 are then patterned to form a gate conductive layer 60 filling trench T and a gate conductive layer 61 on base region 54.

Referring to FIG. 10, an insulating layer is deposited over the resulting structure where gate conductive layers 60 and 61 are formed. Then, the insulating layer is patterned to form an interlayer insulating layer 70 having a gate contact, a source contact, and a drain contact.

A conductive material, e.g., a metal, is deposited over the resulting structure where interlayer insulating layer 70 is formed, and is patterned to form a gate line layer (not shown), a source line layer 81, and a drain line layer 82. The gate line layer is electrically connected to gate conductive layer 60 through the gate contact. Source line layer 81 is electrically connected to source region 56 and base region 54 through the source contact. Drain line layer 82 is electrically connected to drain region 57 through the drain contact.

As discussed above, the trench MOSFET includes both a vertical trench gate and a horizontal gate. Accordingly, the channel current may have a component flowing through the channel formed by the vertical trench gate, and a component flowing through the channel formed by the horizontal gate. Therefore, the efficiency of the trench MOSFET is high and the on resistance of the trench MOSFET may be reduced, thereby improving the electrical properties of the trench MOSFET. The semiconductor device consistent with the present invention may be integrated with other devices through the horizontal drain structure.

Any reference in this specification to “one embodiment,” “an embodiment,” “example embodiment,” etc., means that a particular feature described in connection with the “embodiment” is included in at least one embodiment consistent with the present invention. The appearances of such phrases in various places in the specification are not necessarily referring to the same embodiment. Further, when a particular feature is described in connection with an embodiment, it is submitted that it is within the purview of one skilled in the art to effect such feature in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the appended claims. In addition to variations and modifications in the component parts and/or arrangements, alternative uses will also be apparent to those skilled in the art.

What is claimed is:

1. A semiconductor device, comprising:
a semiconductor substrate of a first conductivity type;
an epitaxial layer of the first conductivity type on the semiconductor substrate;
a base region of a second conductivity type on the epitaxial layer, the base region including subregions spaced apart from one another by a predetermined distance;
a source region of the first conductivity type on the base region;
a drain region of the first conductivity type between the subregions of the base region;
a trench penetrating through the source region and the base region;
a first gate conductive layer within the trench; and
a second gate conductive layer on an exposed portion of the base region.

2. The semiconductor device according to claim 1, wherein the base region has a semicircular or rectangular cross-section.

3. The semiconductor device according to claim 1, wherein the drain region is connected to the semiconductor substrate.

4. A method for fabricating a semiconductor device, comprising:
forming an epitaxial layer of a first conductivity type on a semiconductor substrate of the first conductivity type;
forming a base region of a second conductivity type on the epitaxial layer, the base region including a plurality of subregions spaced apart from one another;
forming a source region of the first conductivity type in the base region, and a heavily-doped region of the first conductivity type between the subregions of the base region;
forming a trench passing through the source region and the base region; and
forming a first gate conductive layer within the trench, and a second gate conductive layer on the base region.

5. The method according to claim 4, wherein the base region has a semicircular or rectangular cross-section.

6. The method according to claim 4, wherein the drain region is connected to the semiconductor substrate.

7. A semiconductor device, comprising:
a first gate region vertical to a substrate;
a second gate region horizontal to the substrate; and
a drain region connected to the substrate.

8. The semiconductor device according to claim 7, wherein the first gate region comprises a trench structure.

9. The semiconductor device according to claim 7, wherein the first gate region and the second gate region form a channel.

10. The semiconductor device according to claim 7, further comprising a base region extending from the first gate region to the second gate region.

11. The semiconductor device according to claim 7, further comprising a heavily-doped region and a lightly-doped base region extending from the first gate region to the second gate region.

12. The semiconductor device according to claim 7, further comprising a base region extending from the first gate region to the second gate region, the base region having a semispherical shape, a semicylindrical shape, or a rectangular-pillar shape.

13. The semiconductor device according to claim 7, wherein the drain region is connected to the substrate.

14. The semiconductor device according to claim 7, wherein the drain region is horizontal to the substrate.

15. The semiconductor device according to claim 7, wherein the first gate region is connected to the second gate region through a conductor.

16. The semiconductor device according to claim 7, wherein the first gate region, the second gate region, and the drain region are formed on an epitaxial layer over the substrate.

17. The semiconductor device according to claim 16, wherein the drain region is connected to the substrate through the epitaxial layer.
